(19) United States
(12) Patent Application Publication
(10) Pub. No.: US 2021/0105912 A1
(43) Pub. Date: Apr. 8, 2021

(54) COOLING DEVICE AND VEHICLE POWER CONVERSION DEVICE

(71) Applicant: Mitsubishi Electric Corporation, Chiyoda-ku, Tokyo (JP)

(72) Inventors: Hirokazu TAKABAYASHI, Chiyoda-ku, Tokyo (JP); Ryosuke NAKAGAWA, Chiyoda-ku, Tokyo (JP); Shigetoshi IPPOSHI, Chiyoda-ku, Tokyo (JP); Masaru SHINOZAKI, Chiyoda-ku, Tokyo (JP); Hiroyuki USHIFUSA, Chiyoda-ku, Tokyo (JP)

(73) Assignee: Mitsubishi Electric Corporation, Chiyoda-ku, Tokyo (JP)

(21) Appl. No.: 16/497,463

(22) PCT Filed: Mar. 31, 2017
(86) PCT No.: PCT/JP2017/013533

§ 371 Date: Sep. 25, 2019

(51) Int. Cl. H05K 7/20

(52) U.S. Cl. CPC H05K 7/20336; H05K 7/20509; H05K 7/20936; H05K 7/209; H05K 7/20409

(57) ABSTRACT

A cooling device includes a base that is a plate-shaped member, heat pipes attached to the base, and a fin attached to the heat pipes. A groove, in which refrigerant is enclosed, is formed in the base. The heat pipes are attached to the base and an internal hollow of each of the heat pipes communicates with the groove. A portion of the groove or both the portion of the groove and a portion of the hollow communicating with the groove are filled with the refrigerant in a liquid state.

### TECHNICAL FIELD

The present disclosure relates to a cooling device and a vehicle power conversion device provided with the cooling device.

### BACKGROUND ART

Semiconductor elements included in a power conversion device generate heat during switching operation thereof. For dissipation of the heat generated by the semiconductor elements, the power conversion device is provided with a cooling device. A semiconductor cooling device disclosed in Patent Literature 1 includes a boiling section in which refrigerant is enclosed, a heat pipe connected to a top portion of the boiling section and communicating with the interior of the boil section, and heat-radiating fins attached to the heat pipe. By pressing the semiconductor device to the boiling section, heat generated by the semiconductor causes the refrigerant to boil. The vaporized refrigerant moves from the boiling section to the heat pipe, and then heat is transferred to the heat-radiating fins. The refrigerant becomes liquid as a result of dissipation of the heat from the heat-radiating fins to outside air, flows along an inner wall of the heat pipe, and returns to the interior of the boiling section. The semiconductor device is cooled by the action of condensation and the action of boiling of the refrigerant inside the boiling section.

### CITATION LIST

### Patent Literature

Patent Literature 1: Unexamined Japanese Patent Application Kokai Publication No. H06-120382

### SUMMARY OF INVENTION

### Technical Problem

Since the boiled and vaporized refrigerant is made to move to the heat pipe in the semiconductor cooling device disclosed in Patent Literature 1, the heat pipe is to be attached to the top face of the semiconductor cooling device in the vertical direction. The number of heat pipes attached to the semiconductor cooling device is restricted by limitations on a position at which the heat pipe is attached to the semiconductor cooling device, thereby causing limitations on cooling capacity of the semiconductor cooling device.

In order to solve the aforementioned problem, an objective of the present disclosure is to improve cooling capacity of a cooling device.

### Solution to Problem

In order to achieve the aforementioned objective, a cooling device according to the present disclosure includes a base, heat pipes and a fin. The base is a plate-shaped member (i) having a first main surface to which an electronic component is attached, and a second main surface, and (ii) having a groove therein, the first main surface and the second main surface being opposite to each other, in a horizontal direction, the groove with refrigerant enclosed extending along the first main surface and the second main surface. Each of the heat pipes has a hollow therein and is attached to the second main surface, and the hollow communicates with the groove. The fin is attached to the heat pipes. The refrigerant is in a gas-liquid two-phase state. A portion of the groove or both the portion of the groove and a portion of the hollow communicating with the groove are filled with the refrigerant in a liquid state.

### Advantageous Effects of Invention

According to the present disclosure, the heat pipes, each having the hollow inside, are attached to the base that internally has the groove with the refrigerant enclosed, and the hollow of each of the heat pipes is made to communicate with the groove, thereby enabling an improvement of the cooling capability of the cooling device.

### BRIEF DESCRIPTION OF DRAWINGS

FIG. 1 is a side view of a cooling device according to Embodiment 1 of the present disclosure;

FIG. 2 is a cross-sectional view of the cooling device according to Embodiment 1;

FIG. 3 is a cross-sectional view of the cooling device according to Embodiment 1;

FIG. 4 is a cross-sectional view of a vehicle power conversion device according to Embodiment 1;

FIG. 5 is a cross-sectional view of the vehicle power conversion device according to Embodiment 1;

FIG. 6 is a drawing illustrating an example of mounting of the vehicle power conversion device according to the Embodiment 1 on a vehicle;

FIG. 7 is a cross-sectional view of a cooling device according to Embodiment 2 of the present disclosure;

FIG. 8 is a cross-sectional view of the cooling device according to Embodiment 2;

FIG. 9 is a cross-sectional view of the cooling device according to Embodiment 2;

FIG. 10 is a cross-sectional view of a cooling device according to Embodiment 3 of the present disclosure;

FIG. 11 is a cross-sectional view of a cooling device according to Embodiment 4 of the present disclosure;

FIG. 12 is a cross-sectional view of the cooling device according to Embodiment 4;

FIG. 13 is a cross-sectional view of a vehicle power conversion device according to Embodiment 4; and

FIG. 14 is a cross-sectional view of a cooling device according to Embodiment 5 of the present disclosure.

### DESCRIPTION OF EMBODIMENTS

Embodiments of the present disclosure are described below in detail with reference to the drawings. Components that are the same or equivalent are assigned the same reference signs throughout the drawings.

### Embodiment 1

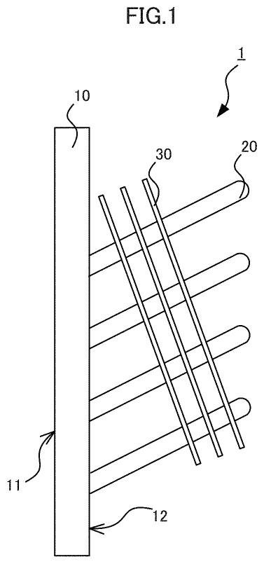

FIG. 1 is a side view of a cooling device according to Embodiment 1 of the present disclosure. A cooling device 1 is provided with a base 10 that is a plate-shaped member, heat pipes 20 attached to the base 10, and fins 30 attached to the heat pipes 20. The number of fins 30 may be freely selected. In the example of FIG. 1, each fin 30 is a plate-shaped member thermally connected to the heat pipes 20. The base 10 has a first main surface 11 to which an electronic component is attached, and a second main surface 12, the first main surface 11 and the second main surface 12 being opposite to each other in the horizontal direction. The heat pipes 20 are attached to the second main surface 12. The cooling device 1 cools the electronic component to be attached to the first main surface 11.

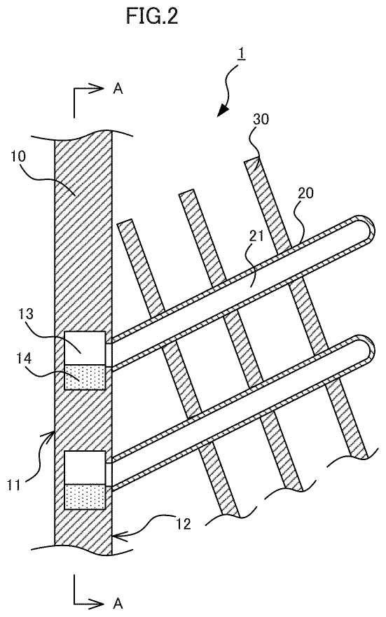

FIG. 2 is a cross-sectional view of the cooling device according to Embodiment 1. A groove 13 extending along the first main surface 11 and the second main surface 12 is formed in the interior of the base 10. Refrigerant 14 is enclosed in the groove 13. The refrigerant 14 is in a gas-liquid two-phase state in which there exist both gaseous refrigerant 14 and liquid refrigerant 14. The refrigerant 14 is, for example, pure water, ethanol, acetone or the like. The heat pipes 20 each have a hollow 21 inside. Each heat pipe 20 is attached to the second main surface 12, and the hollow 21 communicates with the groove 13. Additionally, the second main surface 12 has holes through which the hollow 21 of each of the heat pipes 20 communicates with the groove 13. A portion of the groove 13 or both the portion of the groove 13 and a portion of the hollow 21 communicating with the groove 13 are filled with the liquid refrigerant 14.

On the second main surface 12 being opposite to the first main surface 11 in the horizontal direction, the heat pipes 20 can be attached to any regions that enable communication between the hollow 21 and the groove 13. A reduction in restrictions on positions of the attached heat pipe 20 enables more heat pipes 20 to be attached to the base, thereby enabling an improvement of the cooling capability of the cooling device 1. In the example of FIGS. 1 and 2, among the heat pipes 20, the vertical heights of positions at which some of the heat pipes 20 are attached to the second main surface 12 are different from the vertical heights of positions at which others of the heat pipes 20 are attached to the second main surface 12. The heat pipes 20 are attached to the second main surface 12 to be lined up in the vertical direction, and the hollow 21 of each of the heat pipes 20 is made to communicate with the groove 13 extending in the horizontal direction, thereby enabling the improvement of the cooling capability of the cooling device 1.

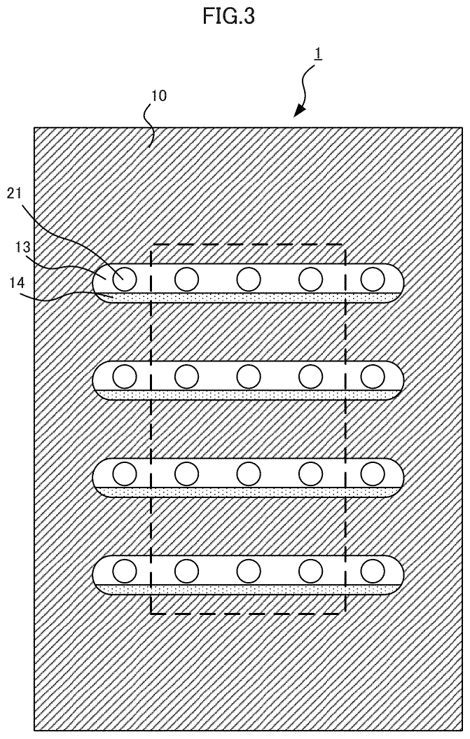

FIG. 3 is a cross-sectional view of the cooling device according to Embodiment 1. FIG. 3 is a cross sectional view taken along the A-A line illustrated in FIG. 2. In Embodiment 1, the groove 13 is a plurality of grooves 13 extending in the horizontal direction, and the grooves 13 are arranged in the vertical direction. In the example of FIG. 3, the hollow 21 of each of the heat pipes 20 communicate with one of the grooves 13. In FIG. 3, a portion surrounded by a dashed line is a portion facing the portion of the first main surface 11 to which the electronic component described below is attached. That is, the portion surrounded by the dashed line in FIG. 3 is where temperature rises due to heat generated by the electronic component. Convection of the refrigerant 14 enclosed in each of the grooves 13 makes the temperature of the refrigerant 14 uniform in the horizontal direction, thereby achieving the horizontal directional equalization of the temperature of the below-described electronic component attached to the first main surface 11.

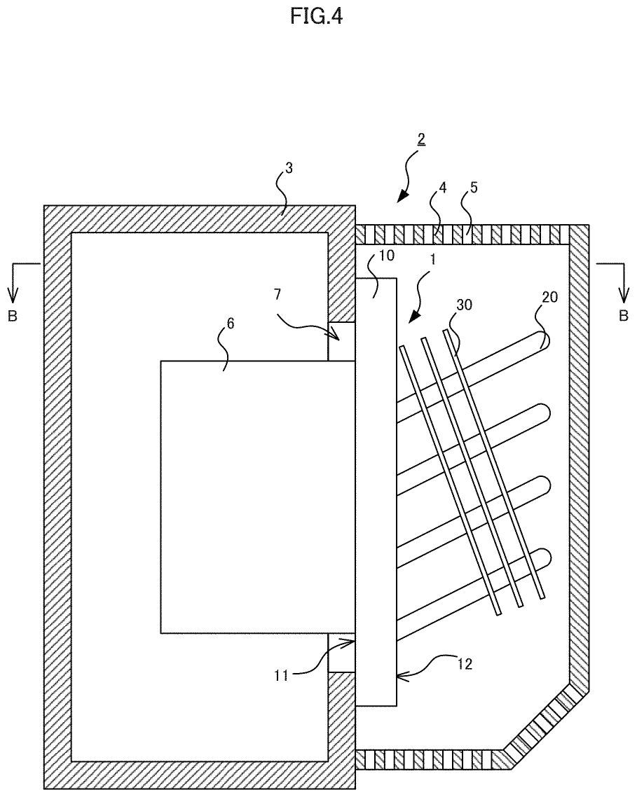

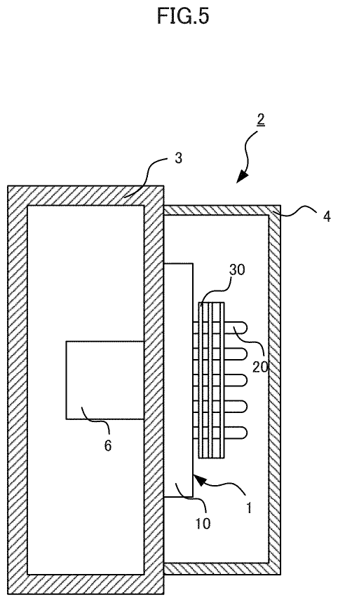

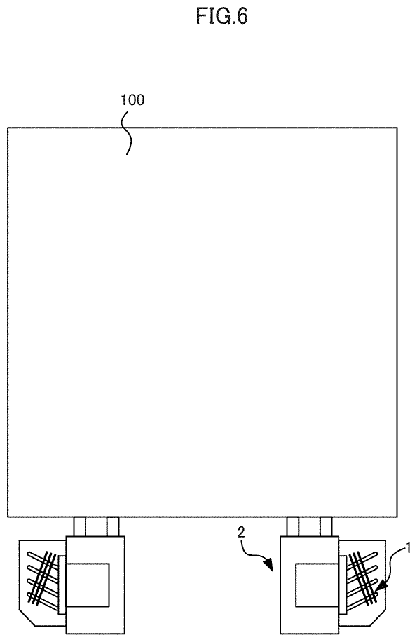

FIG. 4 is a cross-sectional view of a vehicle power conversion device according to Embodiment 1. FIG. 4 is a cross-sectional view in a vertical plane. FIG. 5 is a cross-sectional view of the vehicle power conversion device according to Embodiment 1. FIG. 5 is a cross-sectional view taken along the B-B line illustrated in FIG. 4, that is, a cross sectional view in a horizontal plane. FIG. 6 is a drawing illustrating an example of mounting of the vehicle power conversion device according to the Embodiment 1 on a vehicle. A vehicle power conversion device 2 is provided with a housing 3 and the cooling device 1. The housing 3 accommodates an electronic component 6. The housing 3 has an opening 7. The housing 3 of the vehicle power conversion device 2 is to be disposed under a floor of a vehicle 100. The cooling device 1 is attached to the housing 3. The base 10 of the cooling device 1 covers the opening 7. The first main surface 11 of the base 10 faces the interior of the housing 3. The electronic component 6 is attached to the first main surface 11. Since the base 10 has the grooves 13, the thickness of the base 10 in the direction in which the first main surface 11 and the second main surface 12 are opposite to each other is greater than the thickness of the housing 3. In the example of FIG. 4, the cooling device 1 is covered with a cover 4. The cover 4 has vents 5. Air flowed in from the vents 5 flows while coming into contact with the fin 30. Heat is transferred from the fin 30 to the air, thereby cooling the electronic component 6.

The process of cooling the electronic component 6 by the cooling device 1 is described. Heat generated by the electronic component 6 is transferred to the refrigerant 14 via the first main surface 11 of the base 10. The temperature of the liquid refrigerant 14 rises due to the heat transferred from the electronic component 6, and thus the refrigerant 14 changes to a gas. The vaporized refrigerant 14 flows into the hollow 21 of the heat pipe 20 and rises to the upper end of the hollow 21 in the vertical direction. In the example of FIG. 3, the vaporized refrigerant 14 flows into the hollow 21 of each of the heat pipes 20 communicating with one of the grooves 13 and rises to the upper end of the hollow 21 in the vertical direction. The heat is transferred from the refrigerant 14 to the fins 30 attached to the heat pipes 20 during the rise of the refrigerant 14 to the upper ends of the hollows 21 in the vertical direction. The transfer of the heat from the refrigerant 14 to the fins 30 causes a decrease in the temperature of the refrigerant 14, whereby the refrigerant 14 changes to liquid. The refrigerant 14 in a liquid state flows along the inner circumference surfaces of the heat pipes 20 and then returns to the grooves 13. The fin 30 receiving the heat from the refrigerant 14 transfers heat to the air that flows while coming into contact with the fin 30. The transfer of heat to the air cools the fin 30. As described above, the heat generated by the electronic component 6 is transferred through the refrigerant 14 and the fin 30 to the air, thereby cooling the electronic component 6.

Each inner surface of the grooves 13 has a structure such as a wick, groove, or mesh that generates a capillary action to promote the flow of the refrigerant 14. The heat pipes 20 are attached to the second main surface 12, for example, by brazing. Also, the fin 30 is attached to the heat pipes 20, for example, by brazing. After the heat pipes 20 are attached to the second main surface 12, the refrigerant 14 may be poured in via the vertical-direction upper ends of the heat pipes 20. After the refrigerant 14 is poured vertically into the grooves 13 from the upper ends of the heat pipes 20, the vertical-direction upper ends of the heat pipes 20 are closed. Alternatively, after the refrigerant 14 is poured into the grooves 13 via a non-illustrated inlet formed in the first main surface 11, the inlet may be closed by friction stir welding. Alternatively, the base 10 may be made by carving the grooves 13 in a surface of a first plate-shaped member facing the first main surface 11 included in the first plate-shaped member and by joining the first plate-shaped member and a second plate-shaped member having the second main surface 12 to close the grooves 13. Alternatively, the base 10 may be made by gouging the grooves 13 into a lateral surface of a plate-shaped member having the first main surface 11 and the second main surface 12 and by closing the lateral surface.

In Embodiment 1, the refrigerant 14 having received heat from the electronic component 6 via the first main surface 11 of the base 10 flows from the grooves 13 into the hollow 21 of each of the heat pipes 20, and then transfers the heat to the fins 30 attached to the heat pipes 20. The thermal resistance between the electronic component 6 and the refrigerant 14 is lower as compared with a heat pipe cooler in which a pipe is soldered onto a base plate. Accordingly, the cooling device 1 according to Embodiment 1 has a cooling capability higher than that of this heat pipe cooler.

The electronic component 6 is a power conversion device such as an inverter. The electronic component 6 includes an electronic element made of, for example, a wide bandgap semiconductor having a band gap wider than silicon and an example of the electronic element is a switching element, a diode or the like. The wide bandgap semiconductor is, for example, silicon carbide, gallium nitride-based material, diamond or the like. When the switching element made of the wide bandgap semiconductor is used, switching speed increases, thereby causing an increase in an amount of heat generated by the electronic component 6. The electronic component 6 including the electronic element made of the wide band gap semiconductor can be sufficiently cooled by providing the cooling device 1 according to Embodiment 1.

As described above, in the cooling device 1 according to Embodiment 1, the heat pipes 20 each having the hollow 21 inside are attached to the second main surface 12 of the base 10 having the grooves 13 inside and the hollow 21 of each of the heat pipes 20 is made to communicate with the grooves 13 in which the refrigerant 14 is enclosed, thereby enabling the improvement of the cooling capability of the cooling device 1. Additionally, forming in the interior of the base 10 the grooves 13 extending in the horizontal direction enables equalization of the temperature of the electronic component 6 in the horizontal direction. Since the grooves 13 extending in the horizontal direction are formed in the interior of the base 10, the cooling device 1 according to Embodiment 1 is suitable for a cooling method accompanied by variance in temperatures in the horizontal direction, for example, a cooling method using a headwind during movement of the vehicle, the headwind flowing in the horizontal direction.

### Embodiment 2

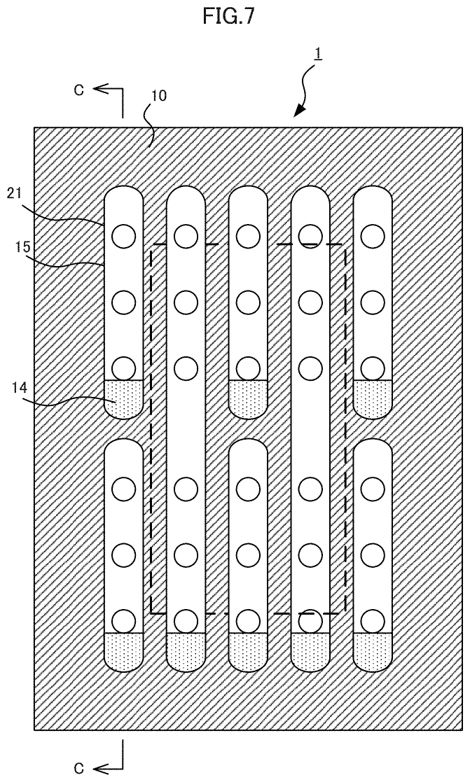

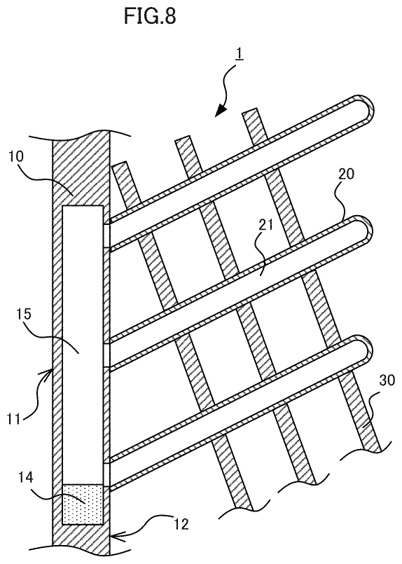

FIG. 7 is a cross-sectional view of a cooling device according to Embodiment 2 of the present disclosure. FIG. 8 is a cross-sectional view of the cooling device according to Embodiment 2. FIG. 8 is a cross-sectional view taken along the C-C line illustrated in FIG. 7. The cross-sectional views in the vertical plane and in the horizontal plane of the vehicle power conversion device 2 including a cooling device 1 according to Embodiment 2 are respectively similar to those of the cross-sectional views of FIGS. 4 and 5. Unlike Embodiment 1, the base 10 of the cooling device 1 according to Embodiment 2 has grooves 15 that each extend in the vertical direction and are arranged in the horizontal direction. As in Embodiment 1, the heat pipes 20 are attached to the second main surface 12, and each hollow 21 communicates with one of the grooves 15. Additionally, the second main surface 12 has holes for making the grooves 15 communicate with the hollow 21 of each of the heat pipes 20. In the example of FIG. 7, the hollow 21 of each of the heat pipes 20 communicates with each of the grooves 15. Portions of the grooves 15 or both the portions of the grooves 15 and a portion of the hollow 21 communicating with the grooves 15 are filled with the liquid refrigerant 14. A portion of the hollow 21 of a heat pipe 20 located on the lowest side in the vertical direction in the heat pipes 20 communicating with the grooves 15 is filled with the liquid refrigerant 14. As a result, even in the hollow 21 of the heat pipe 20 located on the lowest side in the vertical direction, the vaporized refrigerant 14 can flow to the hollow 21.

As in Embodiment 1, the cooling device 1 cools the electronic component 6. In the example of FIG. 7, the vaporized refrigerant 14 flows into the hollow 21 of each of the heat pipes 20 communicating with the grooves 15 and rises to the upper end of the hollow 21 in the vertical direction. Since the refrigerant 14 flows in the vertical direction, the temperature of the electronic component 6 attached to the first main surface 11 is equalized in the vertical direction.

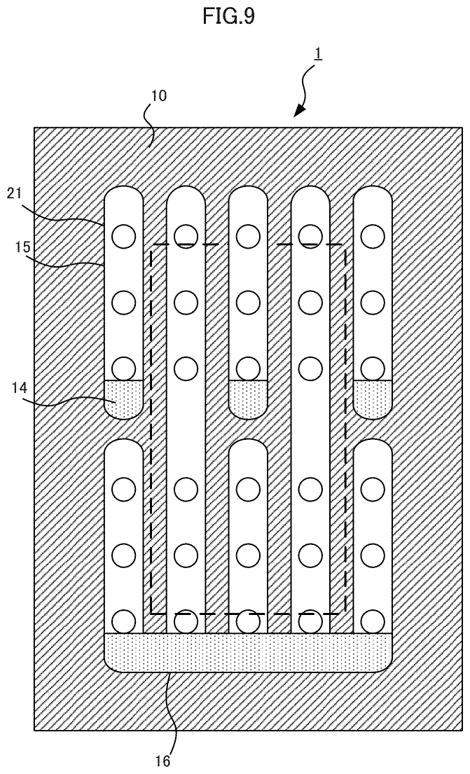

FIG. 9 is a cross-sectional view of the cooling device according to Embodiment 2. The cooling device 1 illustrated in FIG. 9 includes a bypass 16 connecting the vertical directional lower ends of at least some of the grooves 15 among the grooves 15. The use of the bypass 16 causes convection of the refrigerant 14 in the bypass 16, and thus the temperature of the refrigerant 14 is equalized in the horizontal direction by the convection. As a result, the temperature of the electronic component 6 attached to a portion of the first main surface 11 facing the bypass 16 is equalized in the horizontal direction.

The heat pipes 20 are attached to the second main surface 12 side-by-side in the vertical direction and the hollow 21 of each of the heat pipes 20 is made to communicate with one of the grooves 15 extending in the vertical direction, thereby enabling the improvement of the cooling capability of the cooling device 1.

As described above, in the cooling device 1 according to Embodiment 2, the heat pipes 20 each having the hollow 21 inside are attached to the second main surface 12 of the base 10 having the grooves 15 inside and the hollow 21 of each of the heat pipes 20 is made to communicate with the grooves 15 in which the refrigerant is enclosed, thereby enabling the improvement of the cooling capability of the cooling device 1. Additionally, forming in the interior of the base 10 the grooves 15 extending in the vertical direction enables equalization of the temperature of the electronic component 6 in the vertical direction. Since the base 10 includes, inside thereof, the grooves 15 extending in the vertical direction, the cooling device 1 according to Embodiment 2 is suitable for a cooling method in which variance in temperatures can occur in the vertical direction, for example, a cooling method utilizing natural convection.

### Embodiment 3

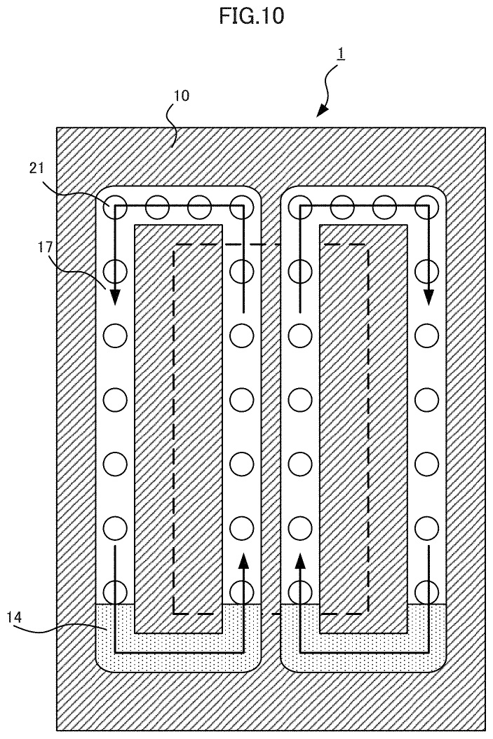

FIG. 10 is a cross-sectional view of a cooling device according to Embodiment 3 of the present disclosure. The cross-sectional views in the vertical plane and in the horizontal plane of the vehicle power conversion device 2 including a cooling device 1 according to Embodiment 3 are respectively similar to those of the cross-sectional views of FIGS. 4 and 5. Unlike Embodiment 1, the base 10 of the cooling device 1 according to Embodiment 3 has annular grooves 17 each having a central axis extending in the direction in which the first main surface 11 and the second main surface 12 are opposite to each other. As in Embodiment 1, the heat pipes 20 are attached to the second main surface 12, and the hollow 21 communicates with one of the grooves 17. Additionally, the second main surface 12 has holes for making the grooves 17 communicate with the hollow 21 of each of the heat pipes 20. In the example of FIG. 10, the hollow 21 of each of the heat pipes 20 communicates with one of the grooves 17. Portions of the grooves 17, or both the portions of the grooves 17 and a portion of the each hollow 21 communicating with the grooves 17, are filled with the liquid refrigerant 14. A portion of the hollow 21 of the heat pipe 20 located on the lowest side in the vertical direction among the heat pipes 20 communicating with one of the grooves 17 is filled with the liquid refrigerant 14. As a result, even in the hollow 21 of the heat pipe 20 located on the lowest side in the vertical direction, the vaporized refrigerant 14 can flow in the hollow 21.

As in Embodiment 1, the cooling device 1 cools the electronic component 6. As indicated by the dashed line in FIG. 10, the electronic component 6 is attached to a portion of the first main surface 11 that faces portions of the grooves 17, thereby causing convection of the refrigerant 14 as indicated by the solid arrows in FIG. 10. The convection of the refrigerant 14 causes equalization of the temperature of the electronic component 6 attached to the first main surface 11. The heat pipes 20 are attached to the second main surface 12 side-by-side in the vertical direction, and the hollow 21 of each of the heat pipes 20 is made to communicate with the grooves 17, thereby enabling the improvement of the cooling capability of the cooling device 1.

As described above, in the cooling device 1 according to Embodiment 3, the heat pipes 20 each having the hollow 21 inside are attached to the second main surface 12 of the base 10 having the grooves 17 inside, and the hollow 21 of each of the heat pipes 20 is made to communicate with the grooves 17 in which the refrigerant 14 is enclosed, thereby enabling the improvement of the cooling capability of the cooling device 1. Additionally, the base 10 including the annular grooves 17 enables the equalization of the temperature of the electronic component 6.

### Embodiment 4

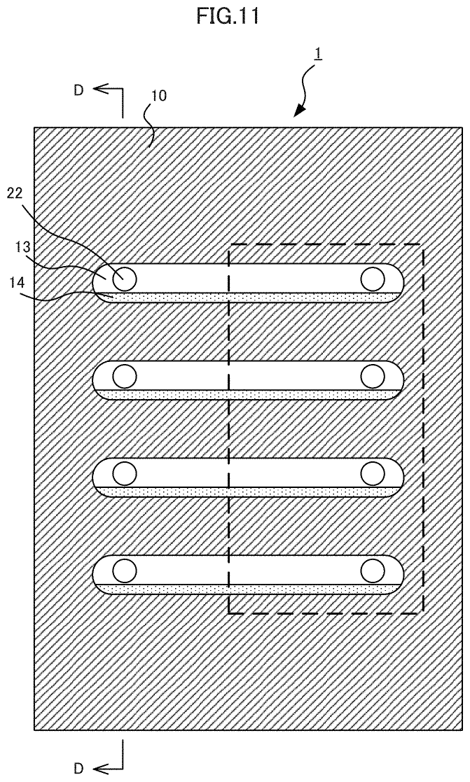

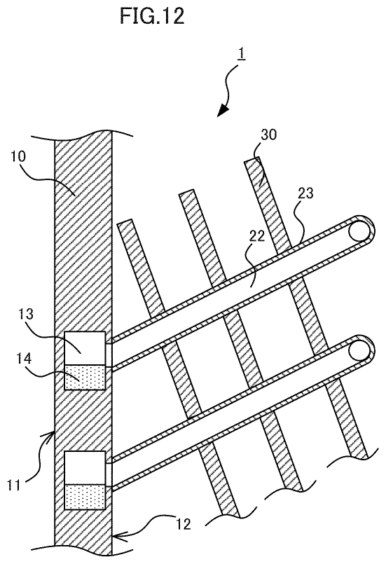

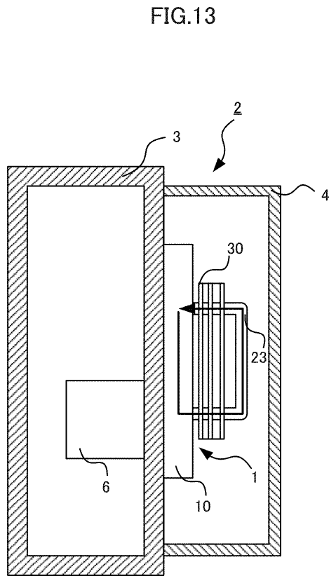

FIG. 11 is a cross-sectional view of a cooling device according to Embodiment 4 of the present disclosure. FIG. 12 is a cross-sectional view of the cooling device according to Embodiment 4. FIG. 12 is a cross sectional view taken along the D-D line illustrated in FIG. 11. FIG. 13 is a cross sectional view of a vehicle power conversion device according to Embodiment 4 of the present disclosure. The cross-sectional view in the vertical plane of a vehicle power conversion device 2 including a cooling device 1 according to Embodiment 4 is similar to the cross-sectional view of FIG. 4. As in the base 10 illustrated in FIG. 3, the base 10 of the cooling device 1 according to the Embodiment 4 has the grooves 13 that extend in the horizontal direction and are arranged in the vertical direction. In the cooling device 1 according to Embodiment 4, both ends of each of heat pipes 23 are attached to the second main surface 12, and the both ends of a hollow 22 of each of the heat pipes 23 communicate with one of the grooves 13. Additionally, the second main surface 12 has holes for making the grooves 13 communicate with hollows 22 of the heat pipes 23. The hollows 22 of the heat pipes 23 and the grooves 13 form annular flow passages.

As in Embodiment 1, heat generated by the electronic component 6 is transferred to the refrigerant 14 via the first main surface 11 of the base 10. The temperature of the liquid refrigerant 14 rises due to the heat transferred from the electronic component 6, and thus the refrigerant 14 changes to a gas. The vaporized refrigerant 14 flows into the hollow 22 of each of the heat pipes 23 and rises to the upper end of the hollow 22 in the vertical direction. The vaporized refrigerant 14 flows into the hollow 22 via, among both ends of the hollow 22 communicating with one of the grooves 13, the end nearer to the position of the attached electronic component 6, and rises to the upper end of the hollow 22 in the vertical direction. The heat is transferred from the refrigerant 14 to the fins 30 attached to the heat pipes 23 during the rise of the refrigerant 14 to the upper end of the hollow 22 in the vertical direction. The transmission of the heat to the fins 30 causes a decrease in the temperature and liquification of the refrigerant 14. The refrigerant 14 in the liquid state flows along the inner circumference surfaces of the heat pipes 23 and then returns to the grooves 13. The fin 30 receiving the heat from the refrigerant 14 transfers heat to the air that flows while coming into contact with the fin 30. The fin 30 is cooled by transferring the heat to the air. As described above, the heat generated by the electronic component 6 is transferred through the refrigerant 14 and the fin 30 to the air, thereby cooling the electronic component 6.

As indicated by the dashed line in FIG. 11, the electronic component 6 is attached to a portion of the first main surface 11 that faces portions of the grooves 13 communicating with one end of the hollow 22, thereby causing convection of the refrigerant 14 in the annular flow passages formed by the hollow 22 and the grooves 13 as indicated by the solid arrows in FIG. 13. The convection of the refrigerant 14 causes the equalization of the temperature of the electronic component 6 attached to the first main surface 11. The heat pipes 23 are attached to the second main surface 12 side-by-side in the vertical direction and the both ends of the hollow 22 of each of the heat pipes 23 are made to communicate with the grooves 13 extending in the horizontal direction, thereby enabling the improvement of the cooling capability of the cooling device 1.

As in Embodiment 1, the heat pipes 23 are attached to the second main surface 12, for example, by brazing. Also, the fin 30 is attached to the heat pipes 23, for example, by brazing. After the heat pipes 23 are attached to the second main surface 12, the refrigerant 14 may be poured in via the vertical-direction upper ends of the heat pipes 23. After the refrigerant 14 is poured into the grooves 13 from the vertical-direction upper ends of the heat pipes 23, the vertical-direction upper ends of the heat pipes 23 are closed. Alternatively, after the refrigerant 14 is poured into the grooves 13 via a non-illustrated inlet formed in the first main surface 11, the inlet may be closed by friction stir welding.

As described above, in the cooling device 1 according to Embodiment 4, the heat pipes 23 each having the hollow 22 inside are attached to the second main surface 12 of the base 10 having the grooves 13 inside and both ends of the hollow 22 of each of the heat pipes 23 are made to communicate with the grooves 13 in which the refrigerant 14 is enclosed, thereby enabling the improvement of the cooling capability of the cooling device 1. Additionally, forming in the interior of the base 10 the grooves 13 extending in the horizontal direction enables equalization of the temperature of the electronic component 6 in the horizontal direction.

### Embodiment 5

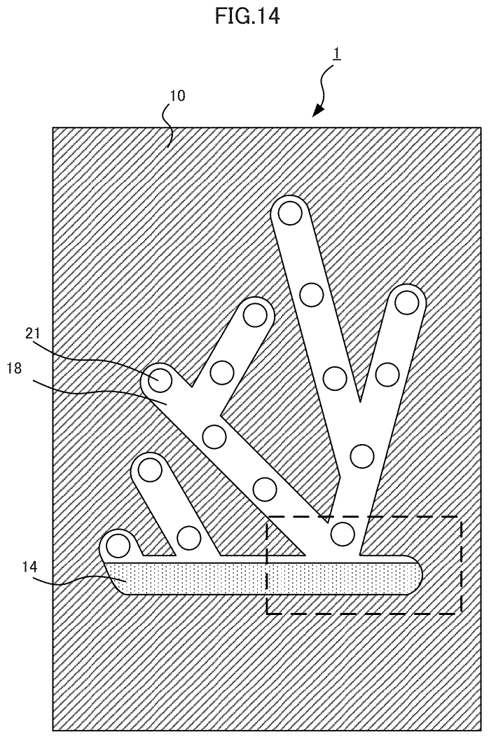

FIG. 14 is a cross-sectional view of a cooling device according to Embodiment 5 of the present disclosure. The cross-sectional views in the vertical plane and in the horizontal plane of the vehicle power conversion device 2 including a cooling device 1 according to Embodiment 5 are respectively similar to the cross-sectional views of FIGS. 4 and 5. Unlike Embodiment 1, the base 10 of the cooling device 1 according to Embodiment 5 has a groove 18 having at least one branch. The heat pipes 20 are attached to the second main surface 12, and the hollow 21 communicates with the groove 18. Additionally, the second main surface 12 has holes for making the groove 18 communicates with the hollow 21 of each of the heat pipes 20. In the example of FIG. 14, the hollow 21 of each of the heat pipes 20 communicates with the single groove 18 having branches. A portion of the groove 18, or both the portion of the groove 18 and a portion of the hollow 21 communicating with the groove 18, are filled with the liquid refrigerant 14. A portion of the hollow 21 of a heat pipe 20 located on the lowest side in the vertical direction among the heat pipes 20 communicating with the groove 18 is filled with the liquid refrigerant 14. As a result, even in the hollow 21 of the heat pipe 20 located on the lowest side in the vertical direction, the vaporized refrigerant 14 can flow in the hollow 21.

The heat pipes 20 are attached to the second main surface 12 side-by-side in the vertical direction, and the hollow 21 of each of the heat pipes 20 is made to communicate with the groove 18, thereby enabling the improvement of the cooling capability of the cooling device 1. As indicated by the dashed line in FIG. 14, the electronic component 6 is attached to a portion of the first main surface 11 that faces a portion of the groove 18, thereby causing convection of the refrigerant 14 in the groove 18 having at least one branch. The convection of the refrigerant 14 enables equalization of the temperature of the electronic component 6.

As described above, in the cooling device 1 according to Embodiment 5, the heat pipes 20 each having the hollow 21 inside are attached to the second main surface 12 of the base 10 having the groove 18 inside and the hollow 21 of each of the heat pipes 20 is made to communicate with the groove 18 in which the refrigerant 14 is enclosed, thereby enabling the improvement of the cooling capability of the cooling device 1. Additionally, forming in the interior of the base 10 the groove 18 having at least one branch enables equalization of the temperature of the electronic component 6.

The present disclosure is not limited to the above-described embodiments, and cooling devices according to the present disclosure can be configured by any combination of two or more of the above-described embodiments. For example, the heat pipes 23 may be attached to the base 10 of the cooling device 1 according to Embodiments 2, 3 or 5. In the above-described example, the base 10 covers the opening 7 from the outside of the housing 3. However, the base 10 may be configured to be provided in the interior of the housing 3 to cover the opening 7 from the inside of the housing 3, and the heat pipes 20 may protrude from the opening 7 to the outside of the housing 3.

The foregoing describes some example embodiments for explanatory purposes. Although the foregoing discussion has presented specific embodiments, persons skilled in the art will recognize that changes may be made in form and detail without departing from the broader spirit and scope of the invention. Accordingly, the specification and drawings are to be regarded in an illustrative rather than a restrictive sense. This detailed description, therefore, is not to be taken in a limiting sense, and the scope of the invention is defined only by the included claims, along with the full range of equivalents to which such claims are entitled.

### REFERENCE SIGNS LIST

1 Cooling device
2 Vehicle power conversion device
3 Housing
4 Cover
5 Vent
6 Electronic component
7 Opening
10 Base
11 First main surface
12 Second main surface
13, 15, 17, 18 Groove
14 Refrigerant
16 Bypass
20, 23 Heat pipe
21, 22 Hollow
30 Fin
100 Vehicle

1. A cooling device comprising:
a base that is a plate-shaped member (i) having a first main surface to which an electronic component is attached and a second main surface, and (ii) having a groove therein, the first main surface and the second main surface being opposite to each other in a horizontal direction, the groove with refrigerant enclosed extending along the first main surface and the second main surface;
heat pipes each having a hollow therein and attached to the second main surface, the hollow communicating with the groove; and
a fin attached to the heat pipes,
wherein
the refrigerant is in a gas-liquid two-phase state, and
a portion of the groove or both the portion of the groove and a portion of the hollow communicating with the groove are filled with the refrigerant in a liquid state.

2-11. (canceled)

12. The cooling device according to claim 1, further comprising:
a brazing member to attach the heat pipes to the second main surface,
wherein
the second main surface of the base has holes through which the hollow of each of the heat pipes communicates with the groove.

13. The cooling device according to claim 1, wherein
vertical heights of positions at which some of the heat pipes are attached to the second main surface are different from vertical heights of positions at which other heat pipes are attached to the second main surface.

14. The cooling device according to claim 12, wherein
vertical heights of positions at which some of the heat pipes are attached to the second main surface are different from vertical heights of positions at which other heat pipes are attached to the second main surface.

15. The cooling device according to claim 1, wherein
the groove is a plurality of grooves each extending in the horizontal direction, and
the grooves are arranged in a vertical direction.

16. The cooling device according to claim 12, wherein
the groove is a plurality of grooves each extending in the horizontal direction, and
the grooves are arranged in a vertical direction.

17. The cooling device according to claim 15, wherein
the hollow of each of the heat pipes communicates with one of the grooves.

18. The cooling device according to claim 15, wherein
both ends of each of the heat pipes are attached to the second main surface,
both ends of the hollow communicate with one of the grooves,
the hollow and the groove form an annular flow passage, and
the electronic component is attached to a portion of the first main surface that faces one end of each of the grooves and does not face another end of each of the grooves.

19. The cooling device according to claim 1, wherein
the groove is a plurality of grooves each extending in a vertical direction, and
the grooves are arranged in the horizontal direction.

20. The cooling device according to claim 12, wherein
the groove is a plurality of grooves each extending in a vertical direction, and
the grooves are arranged in the horizontal direction.

21. The cooling device according to claim 19, wherein
the base includes a bypass therein, the bypass connecting vertical-direction lower ends of at least some of the grooves.

22. The cooling device according to claim 1, wherein
the groove is a plurality of grooves each having an annular shape having a central axis that extends in a direction in which the first main surface and the second main surface are opposite to each other,
the grooves are arranged in the horizontal direction, and
the electronic component is attached to a portion of the first main surface that faces a part of one of adjacent grooves and a part of another one of the adjacent grooves.

23. The cooling device according to claim 12, wherein
the groove is a plurality of grooves each having an annular shape having a central axis that extends in a direction in which the first main surface and the second main surface are opposite to each other,
the grooves are arranged in the horizontal direction, and
the electronic component is attached to a portion of the first main surface that faces a part of one of adjacent grooves and a part of another one of the adjacent grooves.

24. The cooling device according to claim 19, wherein
the hollow of each of the heat pipes communicates with one of the grooves.

25. The cooling device according to claim 1, wherein
the groove has at least one branch, and
the electronic component is attached to a portion of the first main surface that faces at least a portion of vertical-direction lower end of the groove having the at least one branch.

26. The cooling device according to claim 12, wherein
the groove has at least one branch, and
the electronic component is attached to a portion of the first main surface that faces at least a portion of vertical-direction lower end of the groove having the at least one branch.

27. The cooling device according to claim 25, wherein
the hollow of each of the heat pipes communicates with the groove having the at least one branch.

28. The cooling device according to claim 24, wherein
a portion of the groove communicating with the heat pipe located on the lowest side in the vertical direction among the heat pipes, or both the portion of the groove and a portion of the hollow of the heat pipe located on the lowest side in the vertical direction are filled with the refrigerant in a liquid state.

29. A vehicle power conversion device comprising:
a housing configured to accommodate an electronic component therein and to be fixed to a vehicle and having an opening; and
the cooling device according to claim 1, the cooling device being attached to the housing and being configured to cool the electronic component,
wherein
the base of the cooling device covers the opening of the housing,
the first main surface of the base faces an interior of the housing, and
the electronic component to be accommodated in the housing is attached to the first main surface.

30. The vehicle power conversion device according to claim 29, wherein
the electronic component comprises an electronic element made of a wide bandgap semiconductor using silicon carbide, a gallium nitride-based material or diamond.
